(19) United States
(12) Patent Application Publication
(10) Pub. No.: US 2026/0101645 A1
(43) Pub. Date: Apr. 9, 2026

(54) DISPLAY DEVICE

(71) Applicant: Magnolia White Corporation, Tokyo (JP)

(72) Inventors: Tomokazu ISHIKAWA, Tokyo (JP); Hiraaki KOKAME, Tokyo (JP); Akinori KAMIYA, Tokyo (JP); Sho YANAGISAWA, Tokyo (JP)

(73) Assignee: Magnolia White Corporation, Tokyo (JP)

(21) Appl. No.: 19/350,078

(22) Filed: Oct. 6, 2025

(30) Foreign Application Priority Data
Oct. 7, 2024 (JP) 2024-175794

(51) Int. Cl. H10K 59/122; H10K 59/80

(52) U.S. Cl. CPC H10K 59/122; H10K 59/873

(57) ABSTRACT

According to one embodiment, a display device includes a substrate having a display area in which subpixels are provided, a rib layer having a pixel aperture in each of the subpixels, a partition surrounding each of the subpixels and including a lower portion and an upper portion, display elements in each of the subpixels and each including an organic layer, first sealing layers respectively covering each of the display elements, and a second sealing layer covering the first sealing layers. Further, the partition is divided into segments by a slit, and the second sealing layer contacts the rib layer in the slit.

### CROSS-REFERENCE TO RELATED APPLICATIONS

This application is based upon and claims the benefit of priority from Japanese Patent Application No. 2024-175794, filed Oct. 7, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. This type of display devices demands a technique for improving the yield.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of the display device along the III-III line of FIG. 2.

FIG. 4 is a schematic plan view showing some elements of the display device.

FIG. 5 is a schematic cross-sectional view of the display device along the V-V line of FIG. 2.

FIG. 6 is a schematic cross-sectional view of the display device along the VI-VI line of FIG. 2.

FIG. 7 is a schematic plan view of the area surrounded by the frame VII of FIG. 4.

FIG. 8 is a schematic cross-sectional view of the display device along the VIII-VIII line of FIG. 7.

FIG. 9 is a schematic cross-sectional view of the display device along the IX-IX line of FIG. 7.

FIG. 10 is a schematic plan view of a mother substrate according to the first embodiment.

FIG. 11 is a schematic plan view of a panel portion according to the first embodiment.

FIG. 12 is a flowchart showing an example of a manufacturing method of the display device according to the first embodiment.

FIG. 13A is a schematic cross-sectional view showing a manufacturing process of the display device.

FIG. 13B is a schematic cross-sectional view showing a process following FIG. 13A.

FIG. 13C is a schematic cross-sectional view showing a process following FIG. 13B.

FIG. 13D is a schematic cross-sectional view showing a process following FIG. 13C.

FIG. 13E is a schematic cross-sectional view showing a process following FIG. 13D.

FIG. 13F is a schematic cross-sectional view showing a process following FIG. 13E.

FIG. 13G is a schematic cross-sectional view showing a process following FIG. 13F.

FIG. 13H is a schematic cross-sectional view showing a process following FIG. 13G.

FIG. 14 is a schematic plan view of the area surrounded by the frame XIV of FIG. 11.

FIG. 15 is a schematic cross-sectional view of the panel portion along the XV-XV line of FIG. 14.

FIG. 16A is a schematic cross-sectional view showing a comparative example.

FIG. 16B is another schematic cross-sectional view showing the comparative example.

FIG. 16C is still another schematic cross-sectional view showing the comparative example.

FIG. 17A is a cross-sectional view showing effects of the first embodiment.

FIG. 17B is another cross-sectional view showing effects of the first embodiment.

FIG. 17C is a still another cross-sectional view showing effects of the first embodiment.

FIG. 18 is a schematic cross-sectional view of a panel portion according to the second embodiment.

FIG. 19 is a schematic cross-sectional view of a panel portion according to the third embodiment.

FIG. 20 is a schematic cross-sectional view of a panel portion according to the fourth embodiment.

FIG. 21 is a schematic cross-sectional view of a panel portion according to the fifth embodiment.

FIG. 22 is a schematic cross-sectional view of a panel portion according to the sixth embodiment.

FIG. 23 is a schematic cross-sectional view of a panel portion according to the seventh embodiment.

### DETAILED DESCRIPTION

In general, according to one embodiment, a display device includes a substrate having a display area in which a plurality of subpixels are provided, a rib layer having a pixel aperture in each of the plurality of subpixels, a partition surrounding each of the plurality of subpixels and including a lower portion provided above the rib layer and having conductivity and an upper portion having an end portion protruding relative to a side surface of the lower portion, a plurality of display elements provided in each of the plurality of subpixels and including an organic layer emitting light in response to application of a voltage, a plurality of first sealing layers each formed of an inorganic insulating material and respectively covering each of the plurality of display elements, and a second sealing layer formed of an inorganic insulating material and covering the plurality of first sealing layers. Further, the partition is divided into a plurality of segments by a slit. The second sealing layer contacts the rib layer in the slit.

According to another aspect, above at least a part of the partition, end portions of the first sealing layers that are adjacent to each other are spaced apart from each other, and the second sealing layer contacts the upper portion in an area between these end portions.

According to still another aspect, a display device includes a substrate having a display area in which a plurality of subpixels are provided and a surrounding area around the display area, a rib layer provided in the display area and the surrounding area and having a pixel aperture in each of the plurality of subpixels, a first partition surrounding each of the plurality of subpixels and including a lower portion provided above the rib layer and having conductivity and an upper portion having an end portion protruding relative to a side surface of the lower portion, a plurality of display elements provided in each of the plurality of subpixels and including an organic layer emitting light in response to application of a voltage, a plurality of first sealing layers each formed of an inorganic insulating material and respectively covering each of the plurality of display elements, a second sealing layer formed of an inorganic insulating material and covering the plurality of first sealing layers, and a dam portion provided in the surrounding area and surrounding the display area. Further, the rib layer is removed in at least a part of an area between an end portion of the substrate and the dam portion.

Further, according to one embodiment, a manufacturing method of a display device includes forming a rib layer above a substrate, forming a first partition surrounding each of the plurality of subpixels and including a lower portion provided above the rib layer and having conductivity and an upper portion having an end portion protruding relative to a side surface of the lower portion, forming a plurality of display elements provided in each of the plurality of subpixels and including an organic layer emitting light in response to application of a voltage, forming a plurality of first sealing layers each formed of an inorganic insulating material and respectively covering each of the plurality of display elements, forming a second sealing layer formed of an inorganic insulating material and covering the plurality of first sealing layers, and forming a resin layer covering a portion of the second sealing layer.

These configuration of the display device and manufacturing method of the same can improve the yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z direction. The Z-direction is the normal direction of a plane including the X-direction and the Y-direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

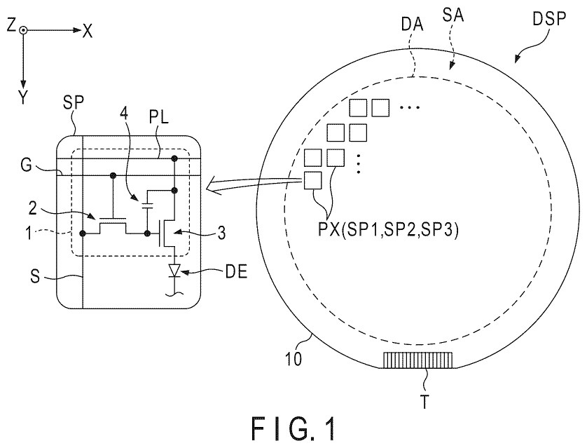

FIG. 1 is a view showing a configuration example of a display device DSP of the first embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP that display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of a source electrode and a drain electrode of the pixel switch 2 is connected to the signal line S. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the illustrated example. For example, the pixel circuit 1 may comprise more thin-film transistors and capacitors.

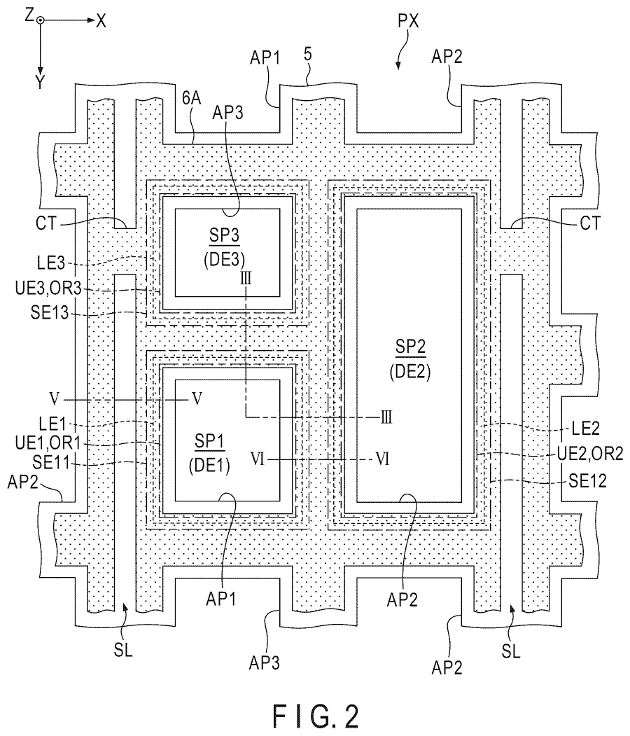

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, each of the pixel apertures AP1, AP2, and AP3 has a rectangular shape. The planar size of the pixel aperture AP1 is greater than that of the pixel aperture AP3. The planar size of the pixel aperture AP2 is greater than that of the pixel aperture AP1. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2.

The lower electrode LE3, the upper electrode UE3, and the organic layer OR3 constitute a display element DE3 of the subpixel SP3. Each of the display elements DE1, DE2, and DE3 may further have a cap layer to be described later. The rib layer 5 surrounds each of the display elements DE1, DE2, and DE3.

A conductive partition 6A (the first partition) is provided above the rib layer 5. The partition 6A functions as lines that apply common voltage to the upper electrodes UE1, UE2, and UE3. The partition 6A entirely overlaps the rib layer 5 and has the same planar shape as that of the rib layer 5. The partition 6A surrounds the subpixels SP1, SP2, and SP3.

The partition 6A has a plurality of slits SL extending in the Y-direction. In the example of FIG. 2, the subpixels SP1, SP2, and SP3 constituting one pixel PX are provided between two slits SL in the X-direction. Further, the partition 6A has a connecting portion CT, which connects portions divided by the slit SL (segments SG to be described later) to each other. The layout of the slits SL and the connecting portion CT is not limited to the example of FIG. 2. For example, slits SL that are continuous between the both end portions in the Y-direction of the display area DA may be provided.

Sealing layers SE11, SE12, and SE13 (the first sealing layers) are provided in the respective subpixels SP1, SP2, and SP3. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 2, the sealing layers SE11, SE12, and SE13 do not overlap the slits SL. In another example, at least one of the sealing layers SE11, SE12, and SE13 may overlap the slit SL.

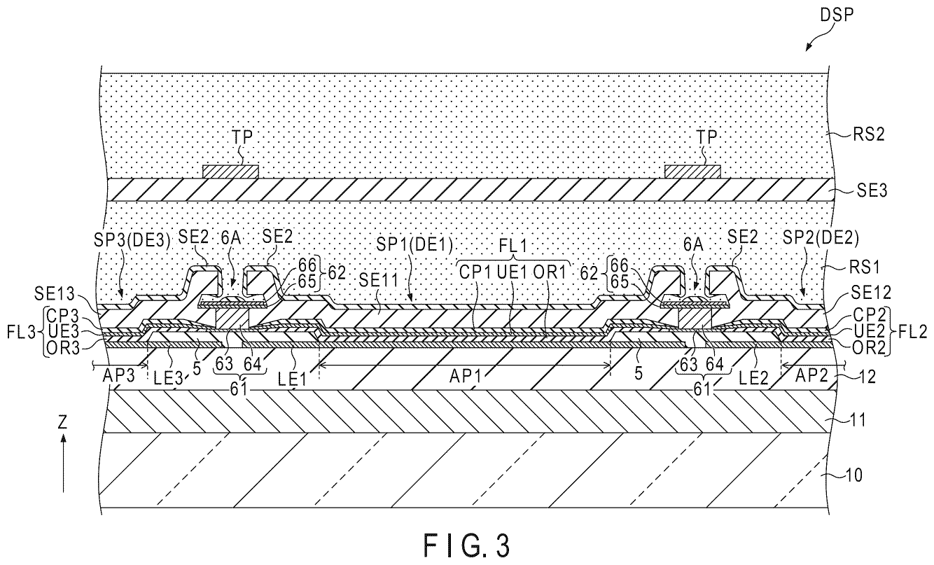

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning line G, the signal line S, and the power line PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. The periphery portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. That is, the partition 6A has an overhang shape in which both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, both end portions of the bottom layer 63 protrude relative to the side surfaces of the stem layer 64.

In the example of FIG. 3, the upper portion 62 comprises a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6A.

The display element DE1 has a cap layer CP1 covering the upper electrode UE1. The display element DE2 has a cap layer CP2 covering the upper electrode UE2. The display element DE3 has a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body having the organic layer OR1, the upper electrode UE1, and the cap layer CP1 is called a stacked film FL1. A multilayer body having the organic layer OR2, the upper electrode UE2, and the cap layer CP2 is called a stacked film FL2. A multilayer body having the organic layer OR3, the upper electrode UE3, and the cap layer CP3 is called a stacked film FL3.

The sealing layers SE11, SE12, and SE13 (the first sealing layers) are provided in the respective subpixels SP1, SP2, and SP3. Further, the sealing layer SE11 continuously covers the stacked film FL1 and the partition 6A around the stacked film FL1. Further, the sealing layer SE12 continuously covers the stacked film FL2 and the partition 6A around the stacked film FL2. Further, the sealing layer SE13 continuously covers the stacked film FL3 and the partition 6A around the stacked film FL3.

In the example of FIG. 3, the sealing layer SE11 located on the partition 6A between the subpixels SP1 and SP2 is spaced apart from the sealing layer SE12 located on this partition 6A. The sealing layer SE11 located on the partition 6A between the subpixels SP1 and SP3 is spaced apart from the sealing layer SE13 located on this partition 6A. Two of the sealing layers SE11, SE12, and SE13 may contact each other above the partition 6A.

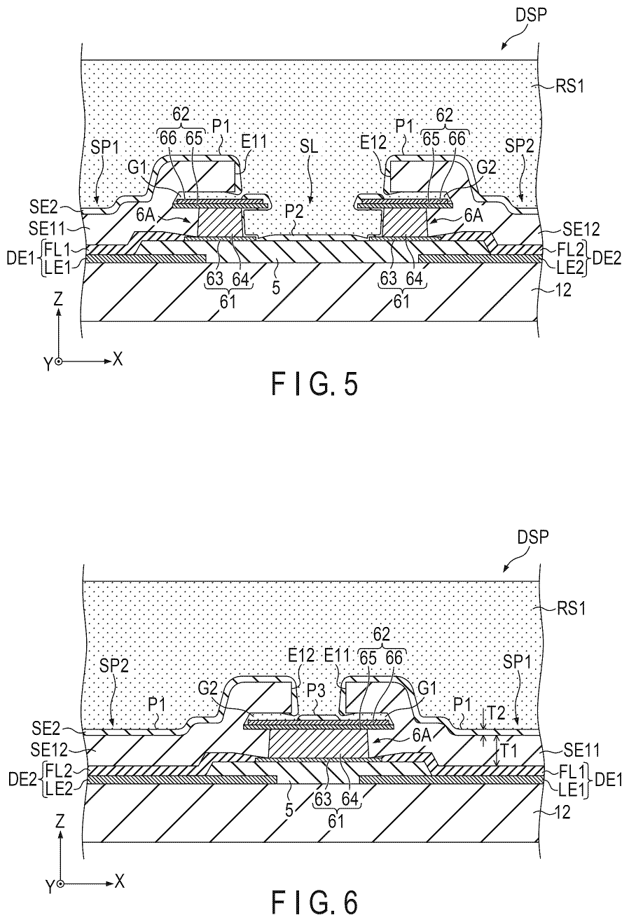

The sealing layers SE11, SE12, and SE13 are covered with a sealing layer SE2 (the second sealing layer). The sealing layer SE2 will be described in detail later with reference to FIG. 5, FIG. 6, and the like.

The sealing layer SE2 is covered with a resin layer RS1. The resin layer RS1 is covered with a sealing layer SE3 (the third sealing layer). The sealing layer SE3 is covered with a resin layer RS2. The resin layers RS1 and RS2 and the sealing layer SE3 are continuously provided in at least the entire display area DA and partly extend in the surrounding area SA as well.

In the example of FIG. 3, a touch panel electrode TP for detecting touch operations by a user is provided on the sealing layer SE3. For example, the touch panel electrode TP is formed of a metal material and has the same shape as that of the partition 6A in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, SE2, and SE3 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, SE2, and SE3 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. In one example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and, OR3 each may have other structures such as a tandem structure including a plurality of light emitting layers.

Each of the cap layers CP1, CP2, and CP3 has, for example, a multilayer structure in which a plurality of transparent layers are stacked. These transparent layers could have a layer formed of an inorganic material and a layer formed of an organic material. These transparent layers have refractive indices different from each other. For example, the refractive indices of these transparent layers differ from the refractive indices of the upper electrodes UE1, UE2, and UE3 and the refractive indices of the sealing layers SE11, SE12, and SE13. At least one of the cap layers CP1, CP2, and CP3 may be omitted.

Each of the bottom layer 63 and the stem layer 64 of the partition 6A is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

The first top layer 65 of the partition 6A is formed of, for example, a metal material. The second top layer 66 of the partition 6A is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, an ITO or an IZO can be used. The upper portion 62 may comprise three or more layers or may consist of a single layer. The upper portion 62 may further include a layer formed of an insulating material.

Common voltage is applied to the partition 6A. This common voltage is applied to each of the upper electrodes UE1, UE2, and UE3 that contact the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage.

Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

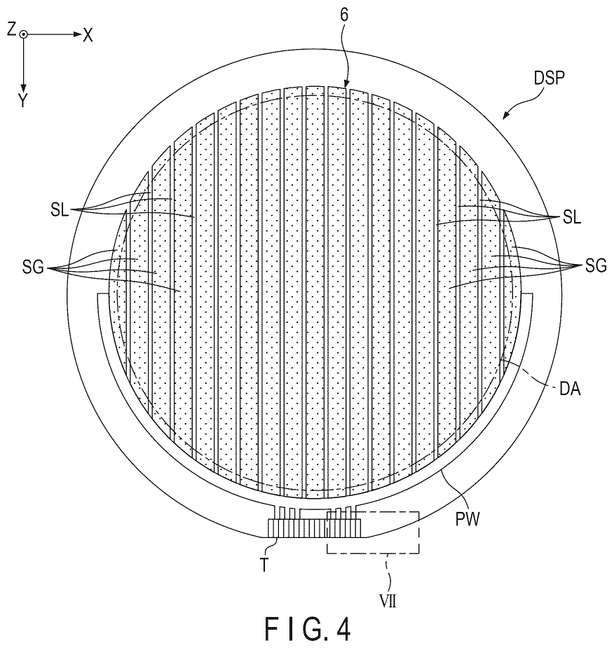

FIG. 4 is a schematic plan view showing some elements of the display device DSP. The partition 6A is divided into the plurality of segments SG by the plurality of slits SL shown in FIG. 2 as well. FIG. 4 schematically shows the slits SL and the segments SG. For example, when the slits SL are located on both sides of the pixel PX in the X-direction as shown in FIG. 2, more slits SL are formed in the display area DA.

At least some of the plurality of segments SG are connected to each other by the connecting portions CT, which cross the slit SL as shown in FIG. 2. On the other hand, the connecting portions CT may not be provided in some of the plurality of slits SL.

An end portion in the extending direction of the slit SL (the Y-direction in the present embodiment) of each of the segments SG is connected to the power supply line PW provided in the surrounding area SA. The power supply line PW is connected to the terminal portion T. Common voltage is applied to each of the segments SG from the terminal portion T via the power supply line PW. In the example of FIG. 4, the other end portions of the segments SG are spaced apart from each other via the slits SL. That is, the other end portions are not connected to each other by a conductive member such as the power supply line PW.

FIG. 5 is a schematic cross-sectional view of the display device DSP along the V-V line of FIG. 2.

This figure shows a part of each of the subpixels SP1 and SP2 adjacent to each other via the slit SL and the partition 6A interposed therebetween. The side surface facing the slit SL of the partition 6A has an overhang shape in which the upper portion 62 protrudes relative to the side surface of the stem layer 64. The rib layer 5 is not open in the slit SL.

In the example of FIG. 5, each of an end portion E11 of the sealing layer SE11 and an end portion E12 of the sealing layer SE12 is located above the partition 6A. That is, the sealing layers SE11 and SE12 do not overlap the slit SL. In another example, the end portions E11 and E12 may be located in the slit SL. In that case, a portion of the slit SL overlaps the sealing layers SE11 and SE12.

A gap G1 (a space) is formed between the upper portion 62 of the partition 6A and the sealing layer SE11 above it. Similarly, a gap G2 (a space) is formed between the upper portion 62 of the partition 6A and the sealing layer SE12 above it. The slit SL is filled with the resin layer RS1. The gaps G1 and G2 may be filled with the resin layer RS1. Alternatively, at least a part of these may be hollow. Further, the respective stacked films FL1 and FL2 may be provided in at least a part of the gaps G1 and G2.

The sealing layer SE2 has a first portion P1 covering the sealing layers SE11 and SE12 and a second portion P2 located in the slit SL. The first portion P1 covers not only the upper surfaces of the sealing layers SE11 and SE12, but also the end portions E11 and E12. Furthermore, in the example of FIG. 5, the first portion P1 also covers the vicinity of the entrance of the gaps G1 and G2 (portions of the ceiling surface of the gaps G1 and G2).

The second portion P2 contacts the rib layer 5 in the slit SL and is covered with the resin layer RS1. Furthermore, the second portion P2 covers the bottom layer 63, the stem layer 64, the first top layer 65, and the second top layer 66 that are exposed from the sealing layers SE11 and SE12 of the partition 6A. More specifically, the second portion P2 directly contacts the bottom layer 63, the stem layer 64, the first top layer 65, and the second top layer 66 that are exposed from the sealing layers SE11 and SE12 of the partition 6A. In the example of FIG. 5, the first portion P1 and the second portion P2 are spaced apart from each other. In another example, the first portion P1 and the second portion P2 may be connected to each other.

FIG. 6 is a schematic cross-sectional view of the display device DSP along the VI-VI line of FIG. 2. This figure shows a part of each of the subpixels SP1 and SP2 and the partition 6A interposed therebetween. In the example of FIG. 6, each of the end portion E11 of the sealing layer SE11 and the end portion E12 of the sealing layer SE12 are both located above the partition 6A and are spaced apart from each other in the X-direction. Further, the gap G1 is formed between the upper portion 62 of the partition 6A and the sealing layer SE11 above it. Similarly, the gap G2 is formed between the upper portion 62 of the partition 6A and the sealing layer SE12 above it.

The space between the end portions E11 and E12 is filled with the resin layer RS1. The gaps G1 and G2 may be filled with the resin layer RS1 as described above, or at least a part thereof may be hollow.

In the cross section of FIG. 6 as well, the first portion P1 of the sealing layer SE2 covers the end portions E11 and E12. Furthermore, the sealing layer SE2 has a third portion P3 located above the partition 6A. The third portion P3 contacts the upper portion 62 (the second top layer 66) in the area between the end portions E11 and E12 and is covered with the resin layer RS1. In the example of FIG. 6, the first portion P1 and the third portion P3 are spaced apart from each other. In another example, the first portion P1 and the third portion P3 may be connected to each other.

The sealing layer SE11 has a thickness T1. The sealing layer SE2 has a thickness T2 smaller than the thickness T1 (T1>T2). In one example, the thickness T2 is half of the thickness T1 or less. Specific numerical values applicable in this case are the thickness T1 of 2.0 μm or more and the thickness T2 of 500 nm to 1.0 μm. For example, the thicknesses of the sealing layers SE12 and SE13 are the same as the thickness T1 of the sealing layer SE11.

FIG. 5 and FIG. 6 show the vicinity of the boundary of the subpixels SP1 and SP2 alone. However, the same configuration can be applied to the vicinity of the boundary of the subpixels SP1 and SP3 and to the vicinity of the boundary of the subpixels SP2 and SP3. The first portion P1 of the sealing layer SE2 also covers the upper surface and the end portions of the sealing layer SE13.

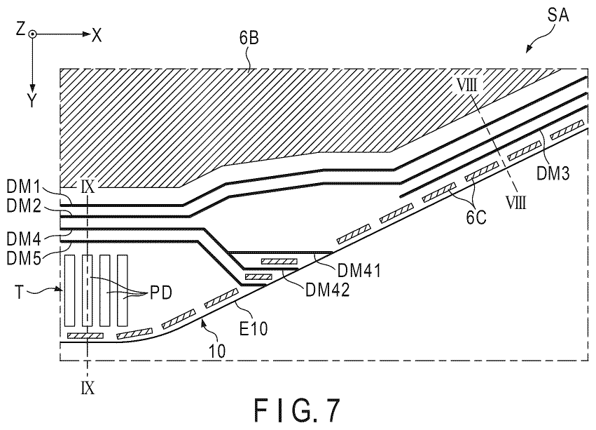

FIG. 7 is a schematic plan view of the area surrounded by the frame VII of FIG. 4. This plan view shows an end portion E10 of the substrate 10 and some elements provided in the vicinity of the end portion E10.

A partition 6B is provided in the surrounding area SA. Although shown in a simplified manner in FIG. 7, the partition 6B has a plurality of apertures. The partition 6B is connected to the partition 6A provided in the display area DA.

Dam portions DM1, DM2, DM3, DM4, and DM5 are provided between the partition 6B and the end portion E10. The dam portions DM1, DM2, and DM3 have ring shapes to surround the display area DA and the partition 6B. However, the dam portion DM3 is interrupted in the vicinity of the terminal portion T.

The dam portions DM4 and DM5 are located between the terminal portion T and the dam portion DM2. The dam portion DM4 branches into dam portions DM41 and DM42 in the vicinity of the end portion E10.

The terminal portion T has a plurality of pads PD. These pads PD have shapes elongated in the Y-direction and are arranged in the X-direction between the dam portion DM5 and the end portion E10. A plurality of partitions 6C (the second partitions) are arranged in the vicinity of the end portion E10. For example, these partitions 6C are arranged at predetermined intervals along the end portion E10.

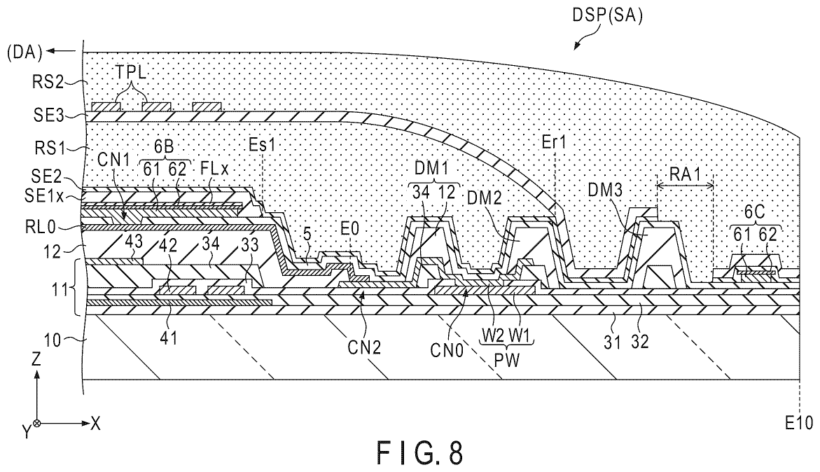

FIG. 8 is a schematic cross-sectional view of the display device DSP along the VIII-VIII line of FIG. 7. The partitions 6B and 6C have the same structure as that of the partition 6A. That is, the partitions 6B and 6C have the lower portion 61 and the upper portion 62. The lower portion 61 has the bottom layer 63 and the stem layer 64. The upper portion 62 has the first top layer 65 and the second top layer 66. At the end portion of each of the partitions 6B and 6C, the upper portion 62 protrudes relative to the side surfaces of the lower portion 61.

The circuit layer 11 shown in FIG. 3 has inorganic insulating layers 31, 32, and 33 formed of inorganic insulating materials, an organic insulating layer 34 formed of an organic insulating material, and metal layers 41, 42, and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

Each of the dam portions DM1, DM2, and DM3 protrudes above the substrate 10. In the example of FIG. 8, the dam portion DM1 is formed of the organic insulating layers 12 and 34. Similarly, the dam portions DM2 and DM3 are formed of the organic insulating layers 12 and 34. In other words, in the present embodiment, the dam portions DM1, DM2, and DM3 are formed of the same materials as the organic insulating layers 12 and 34 on the same layers as the organic insulating layers 12 and 34.

The power line PW to which common voltage is applied is provided below the dam portions DM1 and DM2. The power line PW has a first line W1 formed of the metal layer 42 and a second line W2 formed of the metal layer 43.

In the example of FIG. 8, the first line W1 and the second line W2 contact each other at a contact portion CN0 located between the dam portions DM1 and DM2. A portion of the second line W2 is located between the organic insulating layers 12 and 34 in each of the dam portions DM1 and DM2.

In the surrounding area SA, a conductive relay layer RL0, which connects the partition 6B and the power supply line PW to each other, and the rib layer 5 are provided. For example, the relay layer RL0 is formed of the same material and process as those of the lower electrodes LE1, LE2 and LE3 described above.

The relay layer RL0 is located on the display area DA side (the left side in the figure) relative to the dam portion DM1 and covers the organic insulating layer 12. The rib layer 5 continuously covers the relay layer RL0 and the dam portions DM1, DM2, and DM3.

The partitions 6B and 6C are provided on the rib layer 5. The partition 6B contacts the relay layer RL0 in the contact portion CN1. More specifically, the rib layer 5 is open in the contact portion CN1. The lower portion 61 of the partition 6B (specifically, the bottom layer 63) contacts the relay layer RL0 through this aperture. The contact portion CN1 is provided above the organic insulating layer 12.

The relay layer RL0 contacts the second line W2 of the power supply line PW at a contact portion CN2. The contact portion CN2 is located between an end portion E0 of the organic insulating layer 12 and the dam portion DM1 in plan view.

A stacked film FLx is provided on the partition 6B. The partition 6B and the stacked film FLx are covered with the sealing layer SE1x. The stacked film FLx is formed by the same process and material as those of any of the stacked films FL1, FL2, and FL3 shown in FIG. 3. The sealing layer SE1x is formed by the same process and material as those of any of the sealing layers SE11, SE12, and SE13 shown in FIG. 3. The present embodiment assumes cases where the stacked film FLx and the sealing layer SE1x are respectively formed as the same process and material as those of the stacked film FL3 and the sealing layer SE13, respectively. That is, the stacked film FLx includes the upper electrode UE3, the organic layer OR3, and the cap layer CP3. For example, an end portion Es1 of the sealing layer SE1x is located between the partition 6B and the dam portion DM1.

The sealing layer SE2 is provided in the surrounding area SA as well. The sealing layer SE2 covers the sealing layer SE1x and also covers the rib layer 5 in the area located outside the end portion Es1 of the sealing layer SE1x (on the side of the end portion E10). The sealing layer SE2 covers the partition 6C as well.

The resin layer RS1, the sealing layer SE3, and the resin layer RS2 shown in FIG. 3 are provided above the sealing layer SE2. Further, a touch panel line TPL connected to the touch panel electrode TP shown in FIG. 3 is provided on the sealing layer SE3. For example, the touch panel line TPL is formed of the same material as the touch panel electrode TP.

The resin layer RS1 covers the sealing layer SE2. In the manufacturing of the display device DSP, the dam portions DM1, DM2, and DM3 function to dam up the resin layer RS1 that is uncured. In the example of FIG. 8, the end portion Er1 of the resin layer RS1 is located above the dam portion DM2. That is, the resin layer RS1 partly covers the dam portions DM1 and DM2. The position of the end portion Er1 is not limited to this example.

The sealing layer SE3 covers the end portion Er1 of the resin layer RS1. The sealing layer SE3 contacts the sealing layer SE2 in an area located outside the end portion Er1 (the right side in the figure). In the example of FIG. 8, a removal area RA1 in which the sealing layers SE2 and SE3 have been removed is formed in the vicinity of the dam portion DM3. Even if cracks occur in the sealing layers SE2 and SE3, providing the removal area RA1 can suppress the growth of these cracks toward the display area DA side.

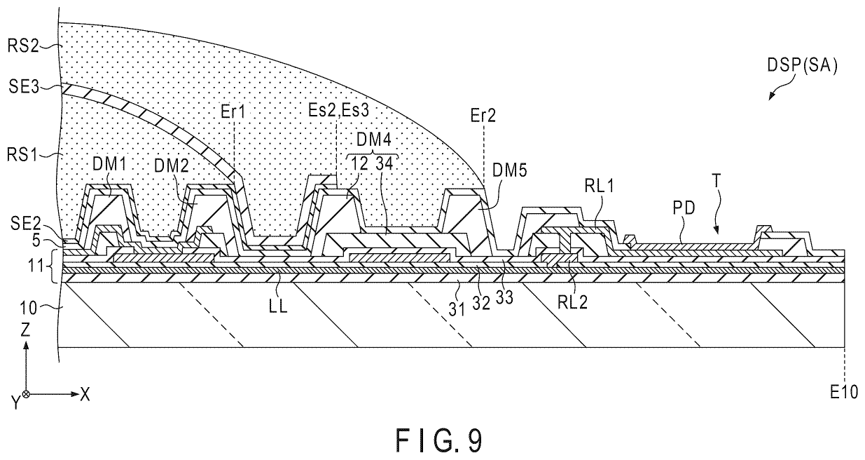

FIG. 9 is a schematic cross-sectional view of the display device DSP along the IX-IX line of FIG. 7. In the same manner as the dam portions DM1, DM2, and DM3, the dam portions DM4 and DM5 are formed of the organic insulating layers 12 and 34.

In the example of FIG. 9, an end portion Es2 of the sealing layer SE2 and an end portion Es3 of the sealing layer SE3 align. For example, these end portions Es2 and Es3 are located above the dam portion DM4 and are covered with the resin layer RS2. The position of each of the end portions Es2 and Es3 is not limited to this example.

For example, the end portion Er2 of the resin layer RS2 is located above the dam portion DM5. The rib layer 5 is also formed in the area located outside the end portion Er2 (on the side of the end portion E10). The pad PD of the terminal portion T is located between the end portions Er2 and E10.

For example, the pad PD is formed of the same material as those of the touch panel electrode TP and the touch panel line TPL. The pad PD is connected to a relay layer RL1. Furthermore, the relay layer RL1 is connected to the relay layer RL2, and the relay layer RL2 is connected to a wiring LL. For example, the relay layer RL1 is formed of the metal layer 43 of the circuit layer 11, the relay layer RL2 is formed of the metal layer 42 of the circuit layer 11, and the wiring LL is formed of the metal layer 41 of the circuit layer 11.

The following will describe an example of the manufacturing method of the display device DSP. In the manufacturing of the display device DSP, a large mother substrate is fabricated, the mother substrate comprising a plurality of areas (panel portions) each including a portion corresponding to the display device DSP.

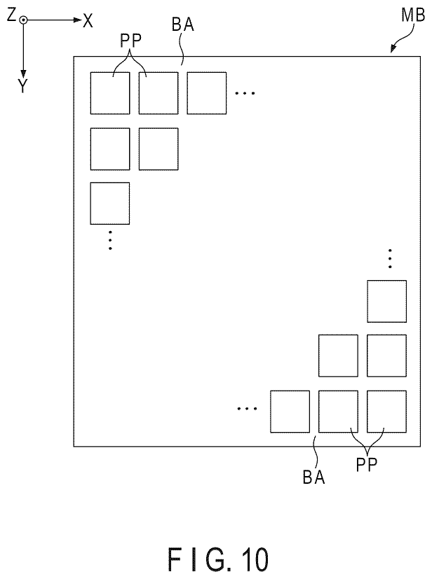

FIG. 10 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel portions PP provided in a matrix and a margin area BA around these panel portions PP. In the example of FIG. 10, the panel portions PP are arranged in the X-direction and the Y-direction via the margin area BA. The layout of the panel portions PP in the mother substrate MB is not limited to this example. In another example, some of the panel portions PP may be arranged without interposing the margin area BA therebetween.

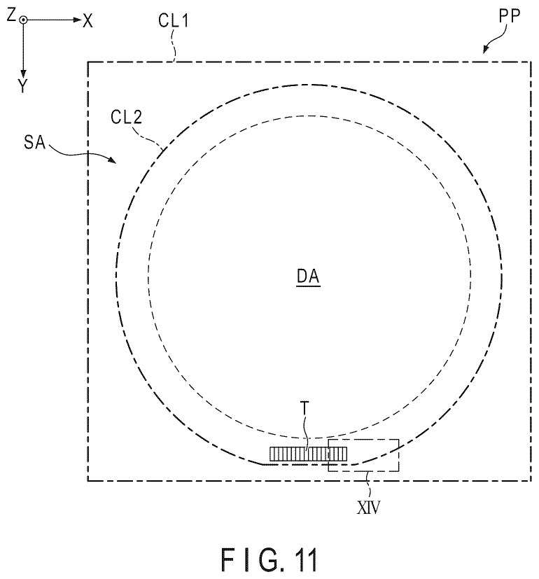

FIG. 11 is a schematic plan view of the panel portion PP. The outer shape of the panel portion PP corresponds to a cut line CL1 for cutting out each panel portion PP from the mother substrate MB.

Each panel portion PP has the display area DA and the surrounding area SA. The surrounding area SA in the panel portion PP corresponds to the area between the display area DA and the cut line CL1.

The surrounding area SA further has a cut line CL2, which is the outer shape of the substrate 10 of the display device DSP. In the manufacturing of the display device DSP, the panel portion PP is cut out from the mother substrate MB along the cut line CL1. Further, the display device DSP is cut out from the panel portion PP along the cut line CL2.

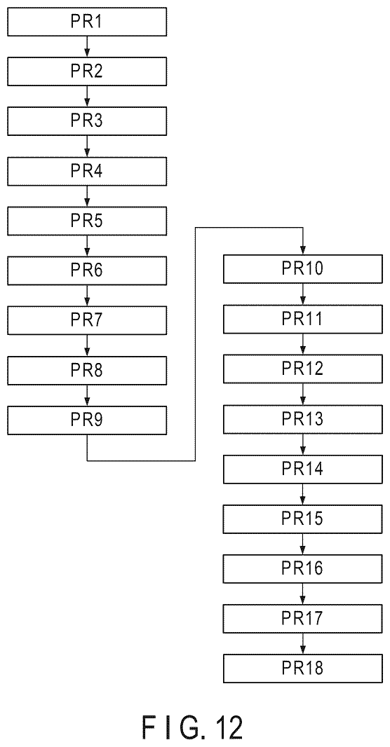

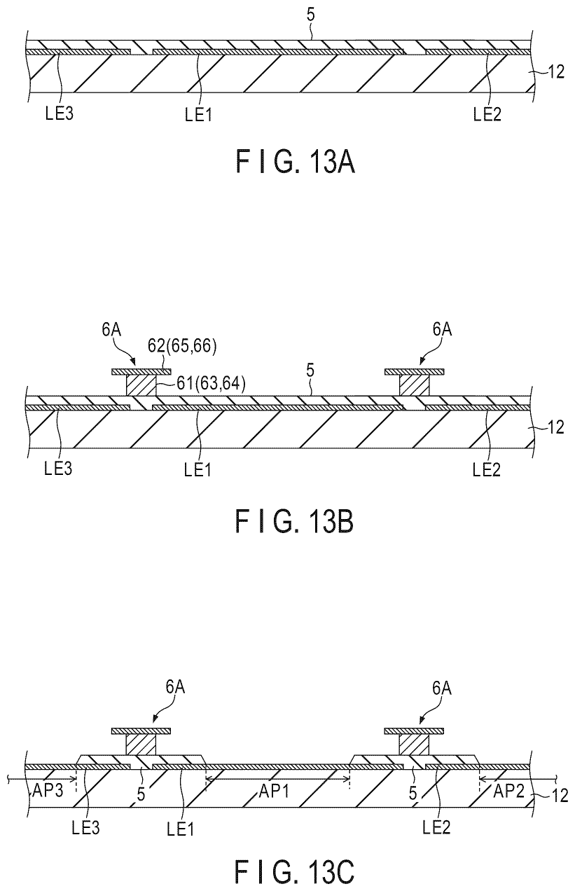

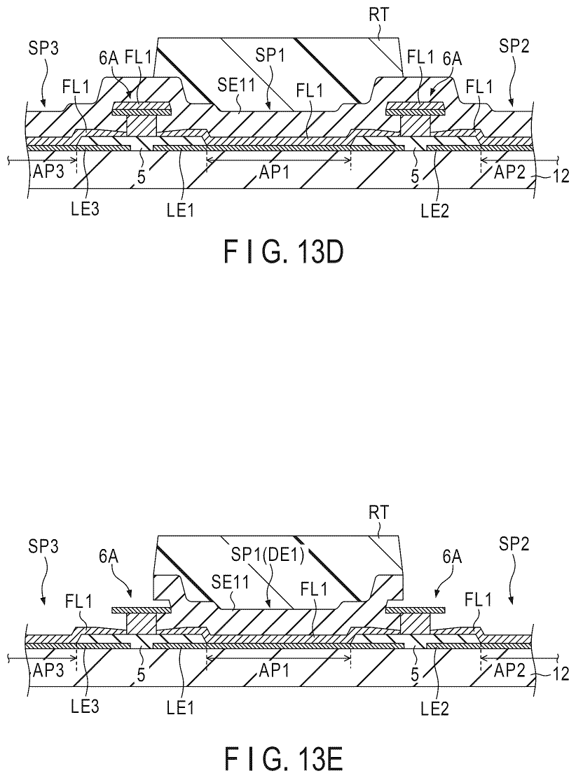

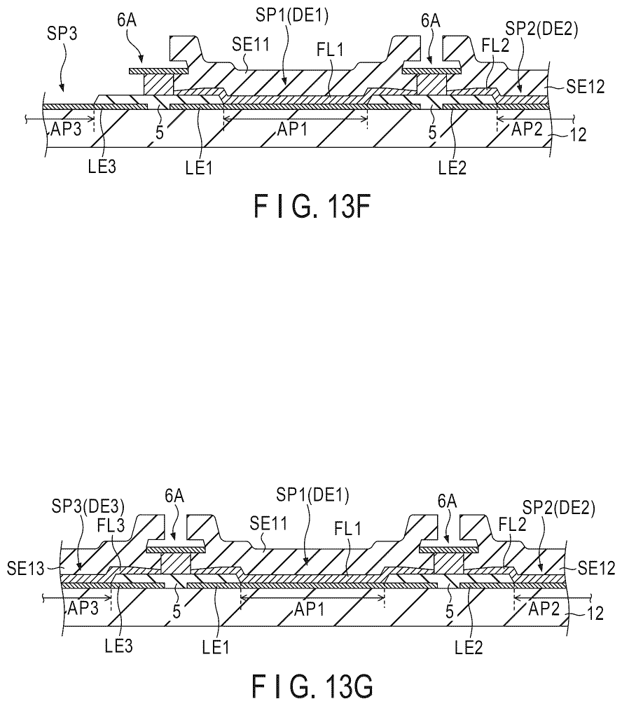

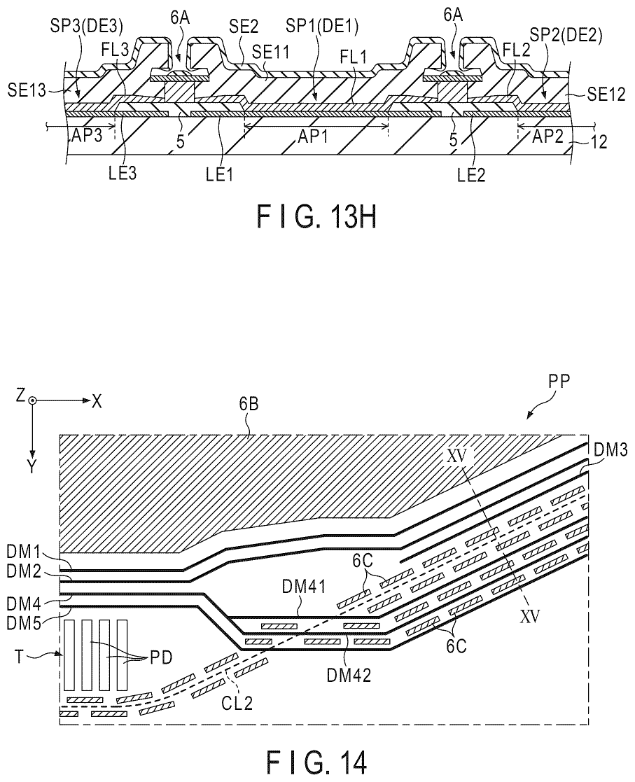

FIG. 12 is a flowchart showing an example of the manufacturing method of the display device DSP. FIG. 13A to FIG. 13H are schematic cross-sectional views showing manufacturing processes of the display device DSP. FIG. 13A to FIG. 13H mainly focus on the display area DA and omit the elements below the organic insulating layer 12.

In the formation of the panel portion PP, first, the circuit layer 11 including the inorganic insulating layers 31, 32, and 33, the organic insulating layer 34, the metal layers 41, 42, and 43, and the like is formed above the substrate 10 of the mother substrate MB (the process PR1 in FIG. 12). Further, the organic insulating layer 12 covering the circuit layer 11 is formed (the process PR2 in FIG. 12). At this time, the dam portions DM1, DM2, DM3, and DM4 are formed as well.

After the process PR2, the lower electrodes LE1, LE2, and LE3 are formed on the organic insulating layer 12 as shown in FIG. 13A (the process PR3 in FIG. 12). Further, the rib layer 5 covering the lower electrodes LE1, LE2, and LE3 is formed in the entire mother substrate MB (the process PR4 in FIG. 12). At this time, the pixel apertures AP1, AP2, and AP3 are not provided in the rib layer 5. The rib layer 5 can be formed by chemical vapor deposition (CVD).

After the formation of the rib layer 5, the partition 6A is formed on the rib layer 5 as shown in FIG. 13B (the process PR5 in FIG. 12). The partitions 6B and 6C of the surrounding area SA are formed together with the partition 6A.

Next, the pixel apertures AP1, AP2, and AP3 are formed in the rib layer 5 as shown in FIG. 13C (the process PR6 in FIG. 12). The pixel apertures AP1, AP2, and AP3 may be formed prior to the formation of the partitions 6A, 6B, and 6C.

After the process PR6, a process for forming the display element DE1 is performed (the process PR7 in FIG. 12). In the formation of the display element DE1, the stacked film FL1 and the sealing layer SE11 are formed first as shown in FIG. 13D. As shown in FIG. 3, the stacked film FL1 has the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed in the entire mother substrate MB including the surrounding area SA and the margin area BA as well as the display area DA of each panel portion PP. The stacked film FL1 is divided by the partitions 6A, 6B, and 6C having overhang shapes. The sealing layer SE11 continuously covers the portions into which the stacked film FL1 is divided, and the partitions 6A, 6B, and 6C.

Subsequently, the stacked film FL1 and the sealing layer SE11 are patterned. In this patterning, a resist RT is provided on the sealing layer SE11 as shown in FIG. 13D. The resist RT covers the subpixel SP1 and a portion of the partition 6A around the subpixel SP1.

Subsequently, an etching process using the resist RT as a mask is performed. By this process, of the stacked film FL1 and the sealing layer SE11, the portions that are exposed from the resist RT are removed as shown in FIG. 13E. That is, of the stacked film FL1 and the sealing layer SE11, the portions that overlap the lower electrode LE1 remain, and the other portions are removed. This process forms the display element DE1 in the subpixel SP1. For example, this etching process removes the stacked film FL1 and the sealing layer SE11 in the surrounding area SA and the margin area BA. This etching process may include wet etching and dry etching performed in order for the sealing layer SE11, the cap layer CP1, the upper electrode UE1, and the organic layer OR1. After these etching processes, the resist RT is removed (stripped).

After the process PR7, a process for forming the display element DE2 is performed (the process PR8 in FIG. 12). The display element DE2 can be formed by the same procedure as that of the display element DE1. That is, in the formation of the display element DE2, the stacked film FL2 and the sealing layer SE12 are formed in the entire mother substrate MB. The stacked film FL2 includes the organic layer OR2 contacting the lower electrode LE2 through the pixel aperture AP2, the upper electrode UE2 covering the organic layer OR2, and the cap layer CP2 covering the upper electrode UE2 as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE2 forms the display element DE2 in the subpixel SP2 as shown in FIG. 13F. For example, the etching in this patterning removes the stacked film FL2 and the sealing layer SE12 in the surrounding area SA and the margin area BA.

After the process PR8, a process for forming the display element DE3 is performed (the process PR9 in FIG. 12). The display element DE3 can be formed by the same procedures as those of the display elements DE1 and DE2. That is, in the formation of the display element DE3, the stacked film FL3 and the sealing layer SE13 are formed in the entire mother substrate MB. The stacked film FL3 includes, the organic layer OR3 contacting the lower electrode LE3 through the pixel aperture AP3, the upper electrode UE3 covering the organic layer OR3, and the cap layer CP3 covering the upper electrode UE3 as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3 as shown in FIG. 13G.

For example, the etching in this patterning removes the stacked film FL3 and the sealing layer SE13 in the most of the surrounding area SA and margin area BA. Of the stacked film FL3 and the sealing layer SE13, the portion that covers the partition 6B remains. In this manner, the remaining portion corresponds to the stacked film FLx and the sealing layer SE1x.

Here, the above description assumes that the display elements DE1, DE2, and DE3 are formed in this order. However, the display elements DE1, DE2, and DE3 may be formed in another order.

After the process PR9, the sealing layer SE2 covering the sealing layers SE11, SE12, and SE13 is formed by, for example, CVD as show in FIG. 13H (the process PR10). The sealing layer SE2 is formed on the entire mother substrate MB including the panel portion PP and the margin area BA.

Subsequently, the resin layer RS1 is formed (the process PR11 in FIG. 12). The resin layer RS1 may be formed by, for example, the ink-jet method. After the process PR11, the sealing layer SE3 is formed by, for example, CVD (the process PR12 in FIG. 12).

After the process PR12, etching is performed to remove the rib layer 5 and the sealing layer SE2, and the sealing layer SE3 that cover the terminal portion T (the process PR13 in FIG. 12). Furthermore, etching is performed to remove the sealing layers SE2 and SE3 over a wider area including the terminal portion T (the process PR14 in FIG. 12). The rib layer 5 is not removed in the process PR14. For example, these etching processes are dry etching. The removal area RA1 shown in FIG. 8 is also formed by the etching in the process PR14.

After the process PR14, the touch panel electrode TP, the touch panel line TPL, and the pad PD are formed (the process PR15 in FIG. 12). Further, the resin layer RS2 is formed (the process PR16 in FIG. 12). The resin layer RS2 may be formed by, for example, the ink-jet method.

After the process PR16, the mother substrate MB is cut along the cut line CL1 (the process PR17 in FIG. 12). Further, the panel portion PP is cut along the cut line CL2 (the process PR18 in FIG. 12). This completes the display device DSP. For example, laser cutting with infrared irradiation along the cut lines CL1 and CL2 may be adopted for cutting in the processes PR17 and PR18. The cutting in the processes PR17 and PR18 may be performed by other methods such as scribe cutting.

FIG. 14 is a schematic plan view of the area surrounded by the frame XIV of FIG. 11. This figure shows some of the elements of the panel portion PP before the cutting along the cut line CL2 (the process PR18) is performed.

The cut line CL2 corresponds to the end portion E10 of the substrate 10 having undergone the step PR18. In FIG. 14, the configuration inside the cut line CL2 (the upper left side in the figure) is the same as the one shown in FIG. 7.

The dam portions DM41, DM42, and DM5 extend outward with respect to the cut line CL2 and surrounds the approximately circular area surround by the cut line CL2 (refer to FIG. 11). In the example of FIG. 14, a plurality of partitions 6C are also provided in the areas between the cut line CL2 and the dam portion DM41, between the dam portions DM41 and DM42, and between the dam portions DM42 and DM5. The partitions 6C may also be provided in areas overlapping the dam portions DM41, DM42, and DM5 and areas located outside the dam portion DM5.

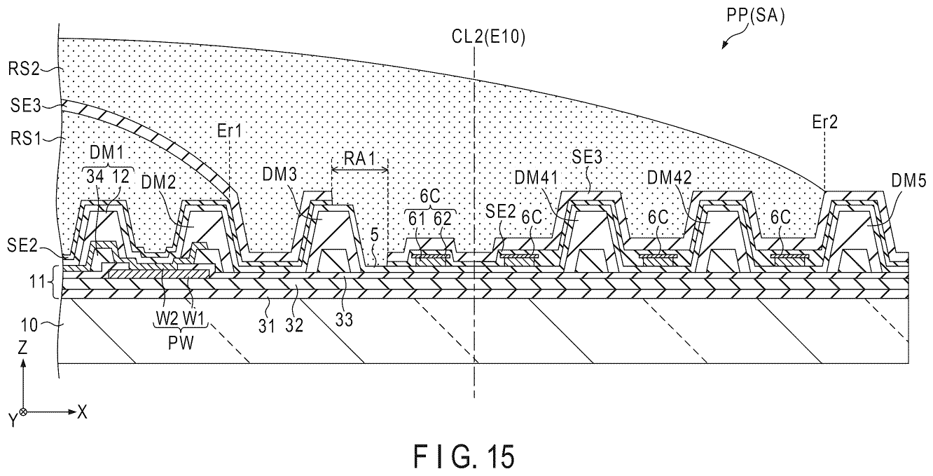

FIG. 15 is a schematic cross-sectional view of the panel portion PP along the XV-XV line of FIG. 14. In the same manner as the dam portions DM1, DM2, and DM3, the dam portions DM41, DM42, and DM5 are formed of the organic insulating layers 12 and 34.

The dam portions DM41, DM42, and DM5 are covered with the rib layer 5, the sealing layer SE2, and the sealing layer SE3. The partition 6C located outside the cut line CL2 is located above the rib layer 5 and is covered with the sealing layer SE2.

In the example of FIG. 15, the cut line CL2 overlaps the inorganic insulating layers 31 to 33, the rib layer 5, the sealing layer SE2, the sealing layer SE3, and the resin layer RS2. However, the cutting line CL2 does not overlap the partition 6C.

The following will describe effects exhibited by the present embodiment.

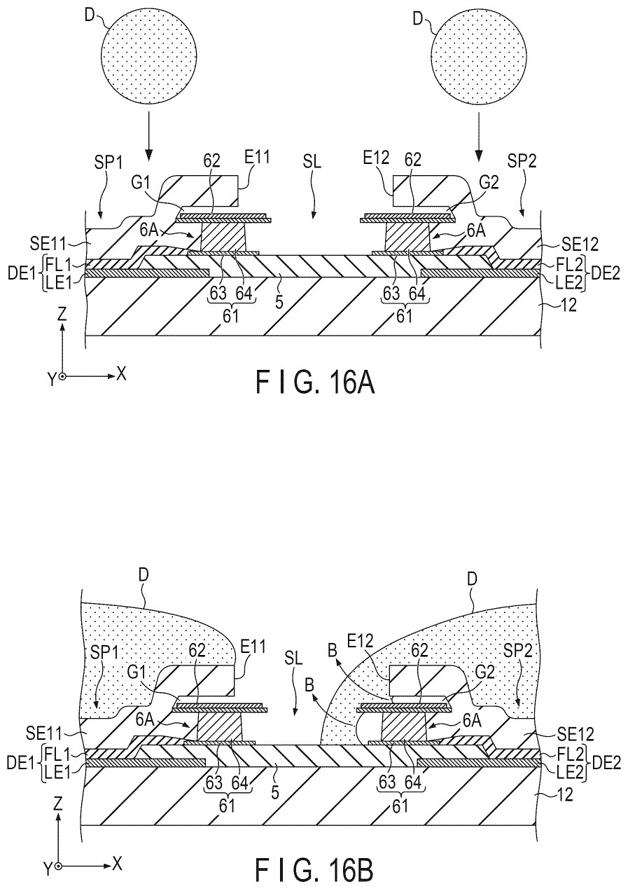

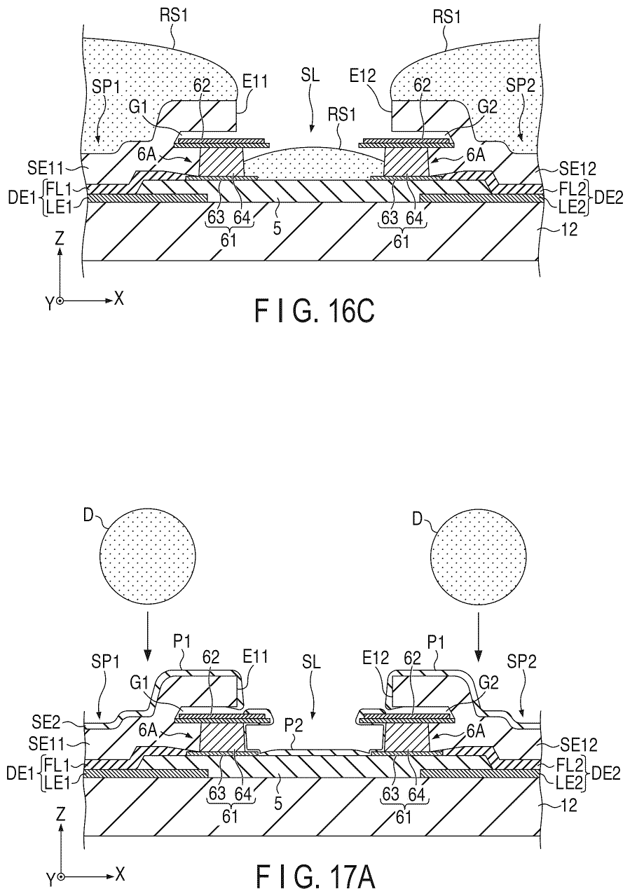

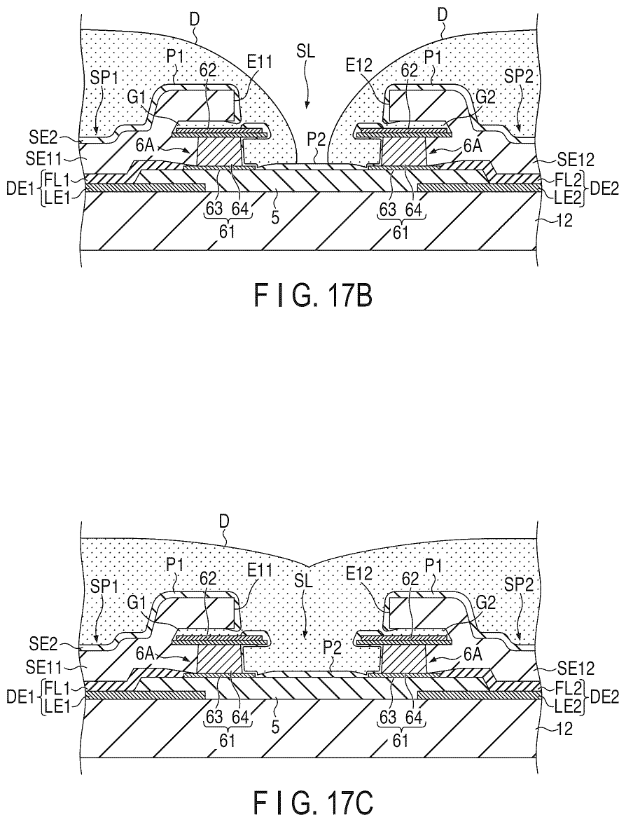

FIG. 16A to FIG. 16C are schematic cross-sectional views of comparative examples to the present embodiment. FIG. 17A to FIG. 17C are schematic cross-sectional views showing effects of the present embodiment. These figures show the configuration around the slit SL as in FIG. 5. The above comparative examples differ from the configuration of the present embodiment in not having the sealing layer SE2.

In the formation of the resin layer RS1 by the ink-jet method, droplets D of resin materials are discharged to each of the panel portions PP as shown in FIG. 16A. Many of these droplets D adhere to the sealing layers SE11, SE12, and SE13.

The droplets D having adhered to the sealing layers SE11, SE12, and SE13 spread as shown in FIG. 16B. The end portions E11 and E12 of the respective sealing layers SE11 and SE12, and the end portions of the sealing layer SE13 are generally vertically cut. Therefore, the droplets D may not flow into the slit SL due to surface tension at these edges as the droplets D on the left side of the figure.

Further, the gap G1 is formed between the upper portion 62 of the partition 6A and the sealing layer SE11 above it. Similarly, the gap G2 is formed between the upper portion 62 of the partition 6A and the sealing layer SE12 above it. Further, a similar gap is formed between the upper portion 62 and the sealing layer SE13. Thus, even if droplets D spread into the slit SL, the air bubbles in these gaps may separate the droplets D when moving in the direction indicated by the arrow B. Furthermore, the side portion facing the slit SL of the partition 6A has an overhang shape. Thus, air bubbles formed in this portion may separate the droplets D.

If the droplets D are cured in a separated state, the resin layer RS1 may deform in the vicinity of the slit SL as show in FIG. 16C. Specifically, the resin layer RS1 may not sufficiently fill the slit SL, resulting in a step corresponding to the slit SL. If the sealing layer SE3 is formed in this state, the sealing layer SE3 may be broken, potentially forming a moisture intrusion path. Furthermore, the touch panel electrode TP formed on the sealing layer SE3 may also be broken.

In contrast, in the present embodiment, the sealing layer SE2 covering the entire display area DA including the sealing layers SE11, SE12, SE13, and the slit SL is provided as shown in FIG. 17A. This sealing layer SE2 covers the end portions E11 and E12 of the respective sealing layers SE11 and SE12, and the end portions of the sealing layer SE13, thereby smoothing the steps at these end portions. Thus, the droplets D can flow into the slit SL more readily as shown in FIG. 17B.

The droplets D are smoothed without being separated by the slit SL as shown in FIG. 17C. This enables the formation of the resin layer RS1 with a flat upper surface as the one shown in FIG. 5. This suppresses the separation of the sealing layer SE3 in the vicinity of the slit SL and the breakage of the touch panel electrode TP.

Thickening the sealing layer SE2 blocks the entrances of the gaps G1 and G2 between the upper portion 62 and the sealing layers SE11 and SE12 as well as the entrance of the gap between the upper portion 62 and the sealing layer SE13. Furthermore, the space below the upper portion 62 facing the slit SL of the partition 6A is also filled to a certain extent by the sealing layer SE2. In this case, the separation of the droplets D due to the air bubbles can be suppressed as well.

The above effects can be obtained not only in the vicinity of the slit SL but also in the positions such as those shown in FIG. 6. That is, the configuration in which the end portions of the sealing layers SE11, SE12, and SE13 are spaced apart from each other above the partition 6A may result in the resin layer RS1 not flowing into the space between these end portions; however providing the sealing layer SE2 can suppress such a situation.

Further, as shown in FIG. 8 and FIG. 9, the sealing layer SE2 contacts the sealing layer SE3 in the surrounding area SA. This allows the resin layer RS1 to be completely surrounded by an inorganic insulating material, thereby further suppressing the occurrence of moisture intrusion path.

Various desirable effects can be obtained from the embodiment in addition to the effects described here.

The following will describe the second to sixth embodiments. The description on these embodiments focus on the same cross-section as the one in FIG. 15 and disclose other configurations applicable to the surrounding area SA of the panel portion PP. Configurations of the panel portion PP that are not particularly referred to may adopt the same configurations as those of the first embodiment. Furthermore, cutting the panel portion PP disclosed in each embodiment along the cutting line CL2 achieves the display device DSP that comprises a configuration inside the cutting line CL2 of the panel portion.

### Second Embodiment

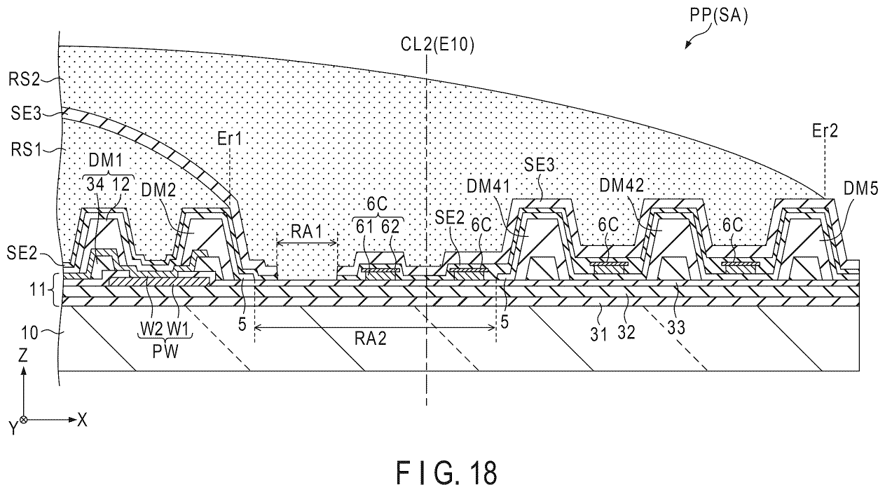

FIG. 18 is a schematic cross-sectional view of the panel portion PP according to the second embodiment. In the present embodiment, the dam portion DM3 is not provided. Further, a removal area RA2 in which the rib layer 5 has been removed is provided between the dam portions DM2 and DM41. For example, the removal area RA2 can be formed in the process of forming the pixel apertures AP1, AP2, and AP3 in the rib layer 5 (the process PR6 in FIG. 12).

The removal area RA2 overlaps the cut line CL2. The end portion of the rib layer 5 located at the edge of the removal area RA2 are covered with the sealing layers SE2 and SE3. The partitions 6C on both sides of the cut line CL2 are located in the removal area RA2. These partitions 6C are provided on the inorganic insulating layer 33 and are covered with the sealing layers SE2.

Omitting the dam portion DM3 as in the present embodiment can narrow the width of the surrounding area SA. Furthermore, the rib layer 5 is removed at the cut line CL2, and thus the cutting of the panel portion PP using the laser cutting is easier.

Cutting the panel portion PP shown in FIG. 18 along the cut line CL2 forms the display device DSP in which the rib layer 5 is removed in a portion between the outermost dam portion DM41 and the end portion E10 of the substrate 10.

### Third Embodiment

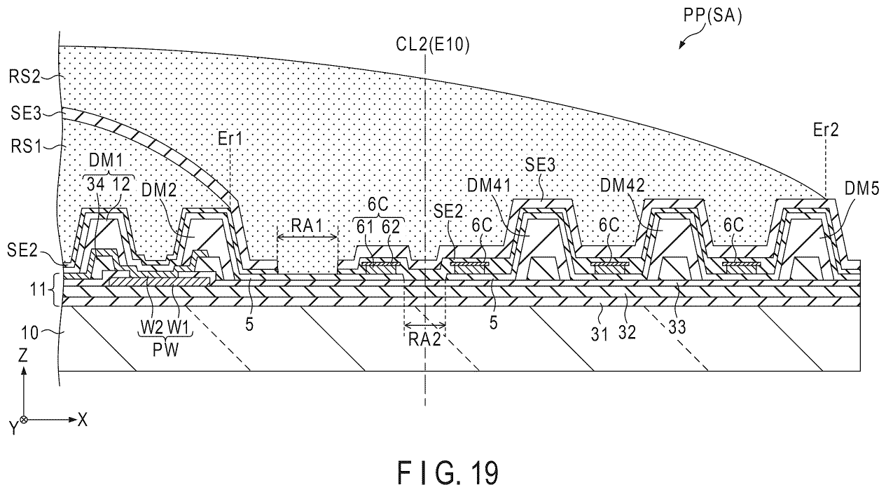

FIG. 19 is a schematic cross-sectional view of the panel portion PP according to the third embodiment. The configuration shown in this figure differs from the second embodiment (FIG. 18) in that the width of the removal area RA2 is narrowed.

Specifically, the removal area RA2 is located between the partitions 6C on both sides of the cut line CL2. This causes the partitions 6C to be located on the rib layer 5, enabling them to be stably formed on the same base as the partition 6A, and the like.

### Fourth Embodiment

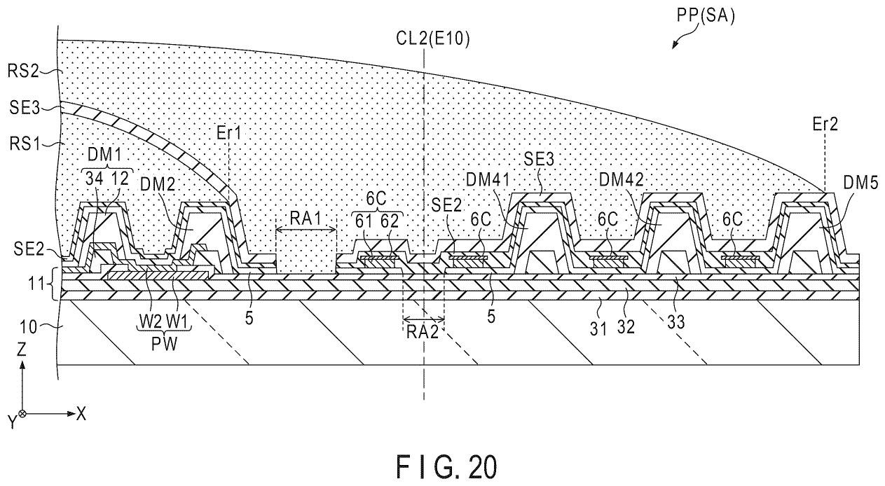

FIG. 20 is a schematic cross-sectional view of the panel portion PP according to the fourth embodiment. The configuration shown in this figure differs from the third embodiment (FIG. 19) in that the rib layer 5 is removed in the removal area RA1.

For example, the removal area RA1 can be formed by etching in the process PR13 shown in FIG. 12. In this case, the edge portions of the rib layer 5, the sealing layer SE2, and the sealing layer SE3 align at the edge of the removal area RA1.

### Fifth Embodiment

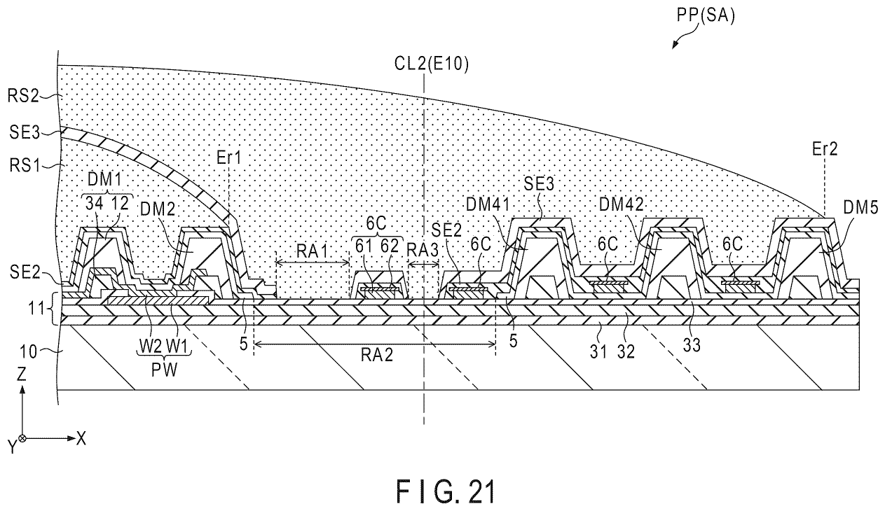

FIG. 21 is a schematic cross-sectional view of the panel portion PP according to the fifth embodiment. The configuration shown in this figure differs from the second embodiment (FIG. 18) in that a removal area RA3 in which the sealing layers SE2 and SE3 have been removed is further provided.

The removal area RA3 overlaps the cut line CL2. More specifically, the removal area RA3 is located between the partitions 6C on both sides of the cut line CL2. For example, the removal area RA3 can be formed by etching in the process PR14 shown in FIG. 12.

When the removal area RA3 is provided as in the present embodiment, the cutting of the panel portion PP using the laser cut described above becomes even easier.

### Sixth Embodiment

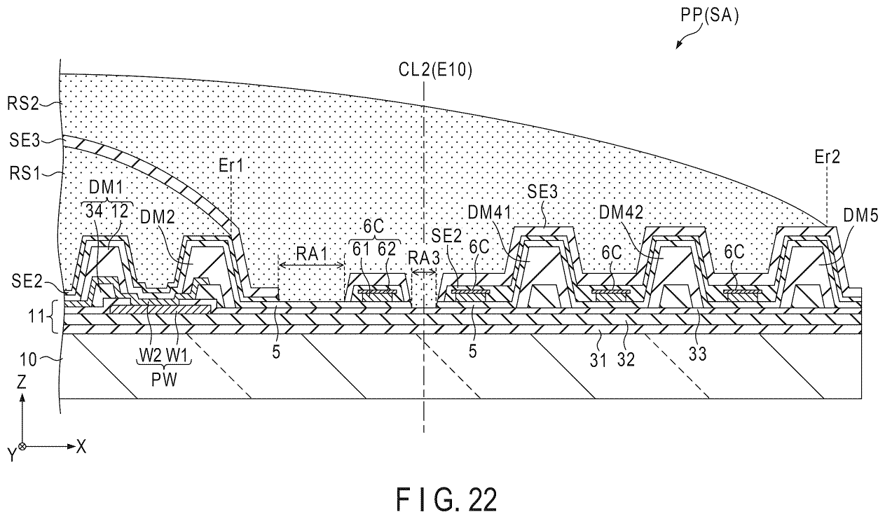

FIG. 22 is a schematic cross-sectional view of the panel portion PP according to the sixth embodiment. The configuration shown in this figure corresponds the configuration of the third embodiment (FIG. 19) with the removal area RA3 provided as in the fifth embodiment (FIG. 21). This configuration achieves the same effects as the third and fifth embodiments.

### Seventh Embodiment

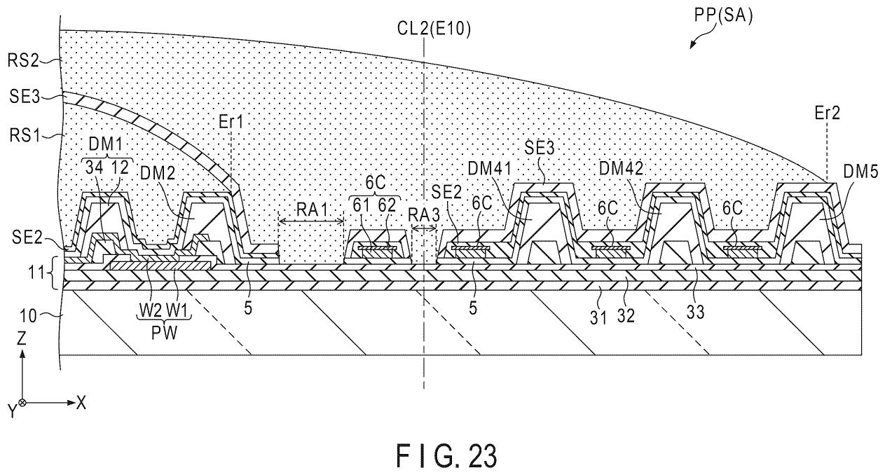

FIG. 23 is a schematic cross-sectional view of the panel portion PP according to the seventh embodiment. The configuration shown in this figure corresponds the configuration of the fourth embodiment (FIG. 20) with the removal area RA3 provided as in the fifth embodiment (FIG. 21). This configuration achieves the same effects as the fourth and fifth embodiments.

In each of the above embodiments, the term “partition”includes various overhanging structures. Even if the overhanging structure has a shape different from the partition disclosed in each embodiment, the portion protruding laterally corresponds to the “upper portion” and the portion recessed below of the portion corresponds to the “lower portion”.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A display device, comprising:
a substrate having a display area in which a plurality of subpixels are provided;
a rib layer having a pixel aperture in each of the plurality of subpixels;
a partition surrounding each of the plurality of subpixels and including a lower portion provided above the rib layer and having conductivity and an upper portion having an end portion protruding relative to a side surface of the lower portion;
a plurality of display elements provided in each of the plurality of subpixels and each including an organic layer emitting light in response to application of a voltage;
a plurality of first sealing layers each formed of an inorganic insulating material and respectively covering each of the plurality of display elements; and
a second sealing layer formed of an inorganic insulating material and covering the plurality of first sealing layers, wherein
the partition is divided into a plurality of segments by a slit, and
the second sealing layer contacts the rib layer in the slit.

2. The display device of claim 1, further comprising:
a resin layer covering the second sealing layer, wherein
at least a part of the slit is filled with the resin layer.

3. The display device of claim 2, wherein
above at least a part of the partition, at least a part of a space between the upper portion of the partition and a first sealing layer of the plurality of first sealing layers is filled with the resin layer.

4. The display device of claim 1, wherein
end portions of the plurality of first sealing layers are located above the partition, and
the second sealing layer covers the end portions of the plurality of first sealing layers.

5. The display device of claim 1, wherein
the second sealing layer has a first portion covering the plurality of first sealing layers and a second portion contacting the rib layer in the slit, and
the first portion and the second portion are spaced apart from each other.

6. The display device of claim 5, wherein
the second portion of the second sealing layer covers the lower portion and the upper portion of the partition.

7. The display device of claim 5, wherein
the second portion of the second sealing layer directly contacts the lower portion and the upper portion of the partition.

8. The display device of claim 1, wherein
the second sealing layer is thinner than the first sealing layer.

9. A display device, comprising:
a substrate having a display area in which a plurality of subpixels are provided;
a rib layer having a pixel aperture in each of the plurality of subpixels;
a partition surrounding each of the plurality of subpixels and including a lower portion provided above the rib layer and having conductivity and an upper portion having an end portion protruding relative to a side surface of the lower portion;
a plurality of display elements provided in each of the plurality of subpixels and each including an organic layer emitting light in response to application of a voltage;
a plurality of first sealing layers each formed of an inorganic insulating material and respectively covering each of the plurality of display elements; and
a second sealing layer formed of an inorganic insulating material and covering the plurality of first sealing layers, wherein
above at least a part of the partition, end portions of the first sealing layers that are adjacent to each other are spaced apart from each other, and the second sealing layer contacts the upper portion in an area between these end portions.

10. The display device of claim 9, further comprising:
a resin layer covering the second sealing layer, wherein
above at least a part of the partition, the space between the end portions of the first sealing layers that are adjacent to each other is filled with the resin layer.

11. The display device of claim 10, wherein
above at least a part of the partition, at least a part of a space between the upper portion of the partition and a first sealing layer of the plurality of first sealing layers is filled with the resin layer.

12. The display device of claim 9, wherein
the second sealing layer covers the end portions of the plurality of first sealing layers.

13. The display device of claim 9, wherein
the second sealing layer includes:
a first portion covering the plurality of first sealing layers; and
a third portion contacting the upper portion, and
the first portion and the third portion are spaced apart from each other.

14. The display device of claim 9, wherein
the second sealing layer is thinner than the first sealing layer.

15. A display device, comprising:
a substrate having a display area in which a plurality of subpixels are provided and a surrounding area around the display area;
a rib layer provided in the display area and the surrounding area and having a pixel aperture in each of the plurality of subpixels;
a first partition surrounding each of the plurality of subpixels and including a lower portion provided above the rib layer and having conductivity and an upper portion having an end portion protruding relative to a side surface of the lower portion;
a plurality of display elements provided in each of the plurality of subpixels and each including an organic layer emitting light in response to application of a voltage;
a plurality of first sealing layers each formed of an inorganic insulating material and respectively covering each of the plurality of display elements;
a second sealing layer formed of an inorganic insulating material and covering the plurality of first sealing layers; and
a dam portion provided in the surrounding area and surrounding the display area, wherein
the rib layer is removed in at least a part of an area between an end portion of the substrate and the dam portion.

16. The display device of claim 15, wherein
the second sealing layer covers an end portion of the rib layer.

17. The display device of claim 15, further comprising:
a resin layer covering the second sealing layer in at least the display area; and
a third sealing layer formed of an inorganic insulating material and covering the resin layer, wherein
the third sealing layer covers an end portion of the rib layer.

18. The display device of claim 17, wherein
an end portion of the second sealing layer and an end portion of the third sealing layer align.

19. The display device of claim 15, further comprising:
a second partition including a lower portion having conductivity and provided in an area in which the rib layer is removed in the surrounding area and an upper portion having an end portion protruding relative to a side surface of the lower portion.

20. The display device of claim 19, wherein
the second sealing layer covers the second partition.
